(19) United States
(12) Patent Application Publication
(10) Pub. No.: US 2023/0204772 A1
(43) Pub. Date: Jun. 29, 2023

(54) DETECTION APPARATUS, DETECTION SYSTEM, AND LIGHT EMITTING DEVICE

(71) Applicant: FUJIFILM Business Innovation Corp., Tokyo (JP)

(72) Inventors: Takafumi HIGUCHI, Kanagawa (JP); Takashi KONDO, Kanagawa (JP); Daisuke IGUCHI, Kanagawa (JP)

(73) Assignee: FUJIFILM Business Innovation Corp., Tokyo (JP)

(21) Appl. No.: 17/723,485

(22) Filed: Apr. 19, 2022

(30) Foreign Application Priority Data
Dec. 27, 2021 (JP) 2021-212819

(51) Int. Cl. G01S 17/36; G01S 17/894; G01S 7/4915; H01S 5/183

(52) U.S. Cl. CPC G01S 17/36; G01S 17/894; G01S 7/4915; H01S 5/18325

(57) ABSTRACT

A detection apparatus includes a light emitting unit including a first light emitting region that has at least one light emitting element and radiates light to a first radiation region and a second light emitting region that has at least one light emitting element and radiates light to a second radiation region, a drive unit that drives the light emitting unit, and a detection unit that detects an object based on a time until light radiated from the light emitting unit is reflected by the object and is received, in which the first radiation region is positioned outside with respect to the second radiation region, and an amount of light radiated from the first light emitting region is greater than an amount of light radiated from the second light emitting region.

### CROSS-REFERENCE TO RELATED APPLICATIONS

This application is based on and claims priority under 35 USC 119 from Japanese Patent Application No. 2021-212819 filed Dec. 27, 2021.

### BACKGROUND

### (i) Technical Field

The present invention relates to a detection apparatus, a detection system, and a light emitting device.

### (ii) Related Art

JP2020-076619A describes a floodlight control apparatus that achieves a reduction in power consumption by achieving efficient power consumption related to floodlight, in regard to an optical distance measurement system. The floodlight control apparatus performs control such that an amount of floodlight is different depending on the presence or absence of detection of a subject and a floodlight mode of a floodlight unit is different between a detection region and a non-detection region of the subject in a case where the subject is detected.

JP2020-120018A describes a light emitting device that can increase optical output by suppressing damage to light emitting characteristics compared to a case where a size of a light emitting point of a light emitting element is made large. The light emitting device includes a light emitting unit in which a plurality of light emitting element groups each having a plurality of light emitting elements are arranged. In the light emitting unit, a plurality of light emitting elements included in the light emitting element group are set in order in a state of light emission or non-light emission in parallel for each of a plurality of light emitting element groups along the arrangement.

JP2019-028039A describes a distance measurement apparatus that performs separation of noise and a signal from an object with satisfactory accuracy while setting a threshold value for detecting the signal to be small. In the distance measurement apparatus, in a case where a scanning region is divided into a plurality of divided regions, and a period from a scanning start of one divided region among all divided regions to a scanning end of all divided regions is defined as single scanning, determination is made whether or not a measurement value of a first divided region is possible as a measurement result of the first divided region based on the measurement value of the first divided region measured by a distance measurement unit during the single scanning and a measurement value of a second divided region measured before the measurement value of the first divided region, and in a case where determination is made that the measurement value of the first divided region is possible as the measurement result of the first divided region, the measurement value of the first divided region is output as a distance to an object in the first divided region.

### SUMMARY

There is known a method that measures a distance to an object to be detected in a radiation range and detects a three-dimensional shape or the like of the object to be detected using a so-called time of flight (ToF) method that radiates light from a light source in a radiation range (so-called field of view: FOV: or field of illumination: FOI) and measures a time until reflected light from an object to be detected is received. In this method, there is an attempt to increase a spread angle of light radiated from the light source using a diffusion plate or the like and to enlarge the radiation range.

Note that length measurement accuracy is deteriorated in a region where the spread angle is large, and a measurement distance is hardly extended.

Aspects of non-limiting embodiments of the present disclosure relate to a detection apparatus, a detection system, and a light emitting device that has an extended measurement distance compared to a case where a light source radiates light uniformly.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a detection apparatus including a light emitting unit including a first light emitting region that has at least one light emitting element and radiates light to a first radiation region and a second light emitting region that has at least one light emitting element and radiates light to a second radiation region, a drive unit that drives the light emitting unit, and a detection unit that detects an object based on a time until light radiated from the light emitting unit is reflected by the object and is received, in which the first radiation region is positioned outside with respect to the second radiation region, and an amount of light radiated from the first light emitting region is greater than an amount of light radiated from the second light emitting region.

### BRIEF DESCRIPTION OF THE DRAWINGS

Exemplary embodiment(s) of the present invention will be described in detail based on the following figures, wherein:

FIG. 1 is a block diagram showing an example of the schematic configuration of a ToF camera to which a first exemplary embodiment is applied;

FIG. 2 is a diagram illustrating a relationship between a light emitting surface and a radiation plane of a light emitting unit according to the first exemplary embodiment;

FIG. 3 is a diagram showing an example of the light emitting unit according to the first exemplary embodiment;

FIGS. 4A and 4B are diagrams illustrating an amount of light in each radiation section, and specifically, FIG. 4A shows a radiation plane, and FIG. 4B is a sectional view taken along the line VIB-VIB of FIG. 4A;

FIG. 5 is a diagram showing a measurement distance L1 in a radiation region F1 and a measurement distance L2 in a radiation region F2 in the ToF camera to which the first exemplary embodiment is applied;

FIG. 6 is a diagram illustrating a light emitting unit of a ToF camera to which the first exemplary embodiment is not applied, for comparison;

FIG. 7 is a diagram showing a measurement distance L′ of the ToF camera to which the first exemplary embodiment is not applied, for comparison;

FIG. 8 is a diagram illustrating a light emitting unit according to a second exemplary embodiment;

FIGS. 9A and 9B are diagrams showing an example of a light emitting unit according to a fourth exemplary embodiment, and specifically, FIG. 9A shows an example of a case where one lens is used, and FIG. 9B shows an example of a case where a lens corresponding to each VCSEL is provided;

FIGS. 10A and 10B are diagrams illustrating a light emitting unit according to a fifth exemplary embodiment, and FIG. 10A shows an example of a light emitting unit to which the fifth exemplary embodiment is applied, and FIG. 10B shows an example of a light emitting unit to which the fifth exemplary embodiment is not applied, for comparison;

FIGS. 11A and 11B are diagrams illustrating a first application example, and FIG. 11A shows an example of a case where the ToF camera to which the first exemplary embodiment is applied is installed on a ceiling of a passage provided between two rows of display racks, and FIG. 11B shows a radiation plane at a position of a two-way arrow of FIG. 11A;

FIGS. 12A and 12B are diagrams illustrating a second application example, and specifically, FIG. 12A shows an example of a case where the ToF camera is installed on a wall surface, and FIG. 12B shows a radiation plane at a position of a two-way arrow of FIG. 12A;

FIGS. 13A and 13B are diagrams illustrating a third application example, and specifically, FIG. 13A shows an example of a case where the ToF camera is mounted in an automobile, and FIG. 13B shows a radiation plane at a position of a two-way arrow of FIG. 13A; and

FIGS. 14A to 14F are diagrams illustrating a detection system with a plurality of ToF cameras, and specifically, FIG. 14A shows a light emitting surface in a ToF camera of the related art for comparison, FIG. 14B shows an example of a detection system with the ToF cameras of the related art shown in FIG. 14A, FIG. 14C is a light emitting surface in a ToF camera, FIG. 14D shows an example of a detection system with the ToF cameras of FIG. 14C, FIG. 14E shows a light emitting surface in another ToF camera, and FIG. 14F shows an example of a detection system with the ToF cameras of FIG. 14E.

### DETAILED DESCRIPTION

Hereinafter, exemplary embodiments of the invention will be described in detail referring to the accompanying drawings.

A detection apparatus that detects a three-dimensional shape or the like of an object to be detected based on a time of flight (ToF) method measures a distance to the object to be detected based on a time from a timing at which light is radiated from a light emitting unit provided in the detection apparatus to a timing at which radiated light is reflected by the object to be detected and is received in a three-dimensional sensor (hereinafter, described as a “3D sensor”) provided in the detection apparatus, and detects the three-dimensional shape. Measuring the distance is described as length measurement or distance measurement. The 3D sensor is an example of a light receiving unit. The ToF method includes an indirect ToF (iToF) method that a time is measured from a difference between a phase of radiated light and a phase of received light, and a direct ToF (dToF) method that directly measures a time from light radiation to reception of light. Here, the indirect ToF method and the direct ToF method are not distinguished and are described as the ToF method.

The three-dimensional shape of the object to be detected may be described as a “three-dimensional image” or a “3D shape”. Then, detecting the three-dimensional shape may be referred to as the measurement of the three-dimensional shape, and may be described as “three-dimensional measurement”, “3D measurement”, or “3D sensing”.

Next, length measurement accuracy in the detection apparatus using the ToF method will be described. The length measurement accuracy is evaluated by a distance resolution σdepth. The distance resolution σdepth corresponding to a minimum distance between two points identifiable by the detection apparatus. Then, as the distance resolution σdepth is smaller, adjacent two points can be identified, and the length measurement accuracy is higher. On the contrary, as the distance resolution σdepth is greater, adjacent two points are hardly identified, and the length measurement accuracy is lower.

In principle, the distance resolution σdepth is influenced by an amount φactive of light (hereinafter, referred to as “measurement light”) radiated from the light emitting unit to the object to be detected. That is, a signal to noise (SN) ratio of an amount (signal) of light received as reflected light from the object to be detected and an amount (noise) of light due to external light or the like as light from other than the light emitting unit is changed depending on the amount φactive of the measurement light, and as a result, the distance resolution σdepth is changed.

Expression (1) shows a relationship between an SN ratio η and the distance resolution σdepth in a case where three-dimensional measurement based on the ToF method is performed. In the expression, c corresponds to a light speed, and Fmod corresponds to a modulation frequency of the measurement light. Expression (2) shows a relationship between the amount φactive of the measurement light and the SN ratio η. In the expression, Apix corresponds to a light receiving element area of a light receiving unit, RE corresponds to a wavelength of the measurement light, FF corresponds to a fill factor of the light receiving unit, Cmod corresponds to modulation contrast, tint corresponds to an integration time, q corresponds to a quantity of electric charge, φambient corresponds to an amount of external light that is radiated to the object to be detected, and Nsystem corresponds to a system noise.

$${σ}_{depth} ≡ \frac{1}{\sqrt{2} η} \cdot \frac{1}{2 π} \cdot \frac{c}{2 {F}_{mod}} \qquad ( 1 )$$

$$η ≡ \frac{{A}_{pix} \cdot RE \cdot FF \cdot {C}_{mod} \cdot {Φ}_{active} \cdot {t}_{int} \cdot \frac{1}{q}}{\sqrt{( {A}_{pix} \cdot RE \cdot FF \cdot ( {Φ}_{active} + {Φ}_{ambient} ) \cdot {t}_{int} \cdot \frac{1}{q} ) + {( {N}_{system} )}^{2}}} \qquad ( 2 )$$

From Expression (1), the greater the SN ratio η, the smaller the distance resolution σdepth, and the smaller the SN ratio η, the greater the distance resolution σdepth. From Expression (2), the greater the amount φactive of the measurement light, the greater the SN ratio η, and the smaller the amount φactive of the measurement light, the smaller the SN ratio η. That is, from Expressions (1) and (2), the greater the amount φactive of the measurement light, the smaller the distance resolution σdepth, and length measurement accuracy is improved. On the contrary, the smaller the amount φactive of the measurement light, the greater the distance resolution σdepth, and the length measurement accuracy is degraded.

Note that the relationship between the amount φactive of the measurement light and the length measurement accuracy is the same in the iToF method and the dToF method.

Here, a fact that an amount of light radiated to an object at a position separated by a certain distance from a light source is proportional to a reciprocal of a square of the distance (inverse square law). That is, as shown in Expression (3), an amount φactive of light radiated to an object to be detected separated by a distance L from the light emitting unit is proportional to a reciprocal 1/L² of a square of the distance L.

$${Φ}_{active} ∝ \frac{1}{{L}^{2}} \qquad ( 3 )$$

From Expressions (1), (2), and (3), the longer the distance L from the light emitting unit to the object to be detected, the smaller the amount φactive of the measurement light, and the length measurement accuracy is degraded. On the contrary, the shorter the distance L, the greater the amount φactive of the measurement light, and the length measurement accuracy is improved.

Accordingly, in the detection apparatus based on the ToF method, there is a “measurement distance” that is a distance capable of performing measurement while securing required length measurement accuracy. Note that the required length measurement accuracy is determined depending on, for example, a purpose of a measurement apparatus or a user's intention. Then, the measurement distance depends on the amount of light radiated from the light emitting unit of the detection apparatus. That is, the greater the amount of radiated light, the longer the measurement distance, and the smaller the amount of radiated light, the shorter the measurement distance.

A measurement apparatus based on the ToF method is applied to recognition of an object to be detected from a measured three-dimensional shape, or the like. For example, the measurement apparatus is used to detect a person who moves on a street or a visitor to a store. Furthermore, for example, the measurement apparatus is mounted in an automobile and is used to perform recognition of an obstacle or measurement of an inter-vehicle distance. In addition, the measurement apparatus is mounted in a self-propelled apparatus, such as a drone, and is used in various surveillance systems.

### First Exemplary Embodiment

ToF Camera 1

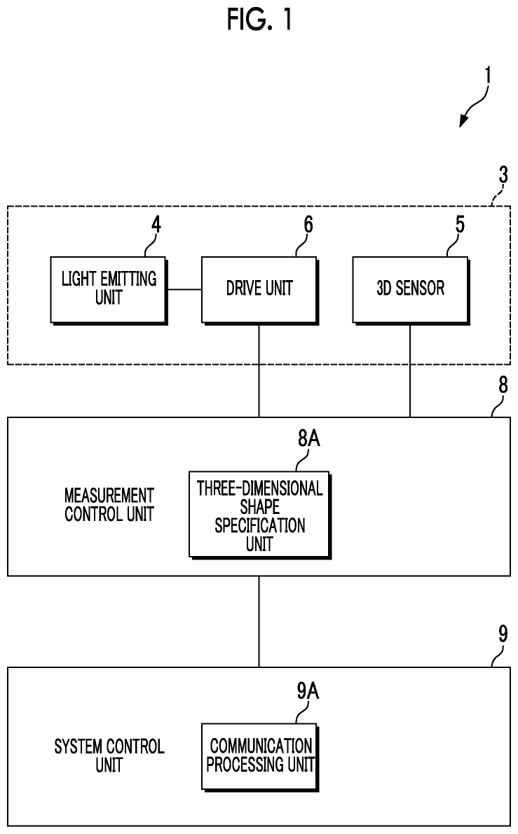

FIG. 1 is a block diagram showing an example of the schematic configuration of a ToF camera 1 to which a first exemplary embodiment is applied. The ToF camera 1 is an example of a detection apparatus.

As shown in the drawing, the ToF camera 1 includes an optical device 3, a measurement control unit 8, and a system control unit 9.

The optical device 3 includes a light emitting unit 4, a 3D sensor 5, and a drive unit 6.

The light emitting unit 4 is a device that is driven by the drive unit 6 and radiates light in a radiation range. The light emitting unit 4 is an example of a light emitting device.

The 3D sensor 5 receives light that, in a case where there is an object to be detected in a radiation range, is reflected by the object to be detected and returned after being radiated from the light emitting unit 4. Then, a three-dimensional shape of the object to be detected is measured based on the ToF method.

The measurement control unit 8 controls the light emitting unit 4 and the 3D sensor 5.

The measurement control unit 8 includes a three-dimensional shape specification unit 8A. The three-dimensional shape specification unit 8A measures a distance to the object to be detected based on a time from when the light emitting unit 4 radiates light until the 3D sensor 5 receives light and detects the three-dimensional shape of the object to be detected. The three-dimensional shape specification unit 8A is an example of a detection unit.

The system control unit 9 controls the ToF camera 1 as a system. The system control unit 9 may include, for example, a communication processing unit 9A that performs communication with another apparatus via a network. The communication processing unit 9A executes processing or the like of transmitting information regarding the three-dimensional shape of the object to be detected specified by the three-dimensional shape specification unit 8A to another apparatus.

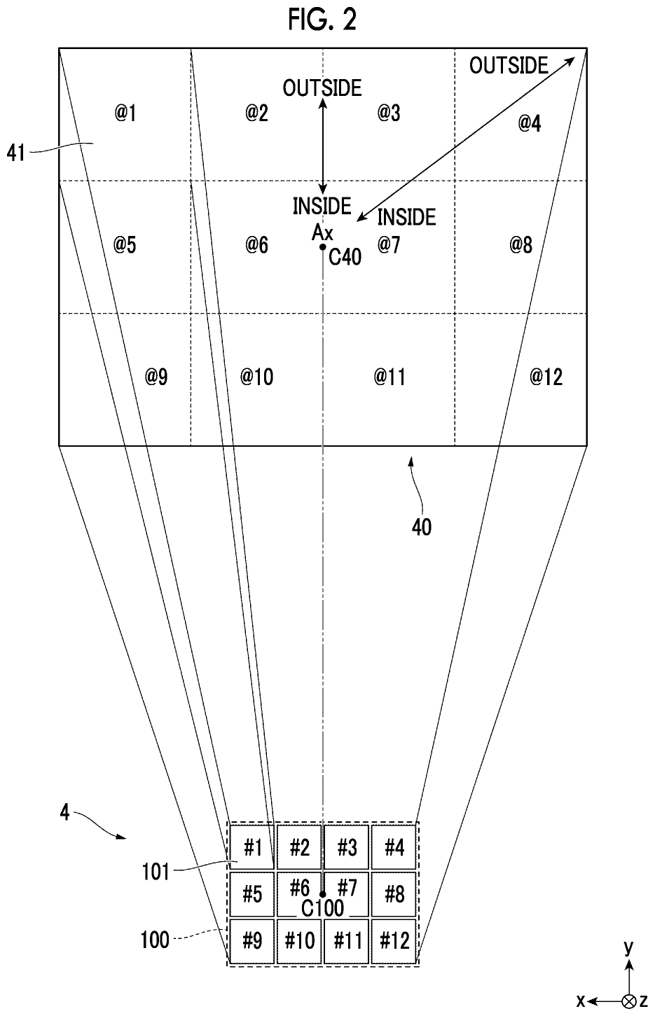

FIG. 2 is a diagram illustrating a relationship between a light emitting surface 100 of the light emitting unit 4 and a radiation plane 40 according to the first exemplary embodiment. In FIG. 2, a left direction of the paper is referred to as the x direction, an upward direction of the paper is referred to as the y direction, and a back side direction of the paper is referred to as the z direction. Although the light emitting surface 100 and the radiation plane 40 are shown to be deviated in an up-down direction (±y direction) of the paper, the light emitting surface 100 and the radiation plane 40 are disposed to face each other. In FIG. 2, the light emitting unit 4 is positioned in a front side direction (−z direction) of the paper, and the radiation plane 40 is positioned in aback side direction (+z direction) of the paper.

The light emitting unit 4 comprises a light emitting surface 100 on which a plurality of vertical cavity surface emitting lasers (hereinafter, referred to as “VCSELs”) are arranged. Light is radiated with light emission of the VCSEL. The VCSEL is an example of a light emitting element. In FIG. 2, the VCSEL is omitted.

The light emitting surface 100 is divided into a plurality of light emitting sections 101 each including at least one VCSEL. Here, as an example, the light emitting surface 100 is divided into 12 light emitting sections 101 in total of four light emitting sections in the x direction and three light emitting sections in the y direction. As shown in the drawing, in a case where there is no need to distinguish the light emitting sections 101, the light emitting sections 101 are distinguished as light emitting sections #1 to #12 in order from an upper left side (an end in the +x direction and the +y direction) in FIG. 2.

In the specification, “to” indicates a plurality of constituent elements distinguished individually by numbers, and means that elements before and after “to” and elements with numbers between the elements are included. For example, the light emitting sections #1 to #12 includes 12 light emitting sections 101 from the light emitting section #1 to the light emitting section #12.

Each light emitting section 101 is driven independently by the drive unit 6 (see FIG. 1) to emit light. The drive of the light emitting section 101 indicates that power is supplied to the VCSEL included in the light emitting section 101 and the VCSEL emits light. The term “drive independently” indicates that the VCSEL is driven for each light emitting section 101 to emit light. The drive unit 6 drives each light emitting section 101 in response to a control signal from the measurement control unit 8 (see FIG. 1).

Accordingly, the light emitting sections #1 to #12 in the example of FIG. 2 do not always emit light simultaneously, and for example, may be in a state in which, while the light emitting section #1 emits light, the light emitting section #12 does not emit light.

The radiation plane 40 is a plane that is perpendicular to a direction in which light is radiated, at a certain distance from a center C100 of the light emitting surface 100 and to which light from the light emitting unit 4 is radiated.

In the example of FIG. 2, since the light emitting unit 4 radiates light toward the z direction, the radiation plane 40 spreads in the x direction and the y direction at a certain distance in the z direction. A central axis Ax (two-dot chain line) that passes through a center C40 of the radiation plane 40 and the center C100 of the light emitting surface 100 is perpendicular to the light emitting surface 100 and the radiation plane 40. In the first exemplary embodiment, with the light emitting surface 100 having a rectangular shape, the radiation plane 40 has a rectangular shape.

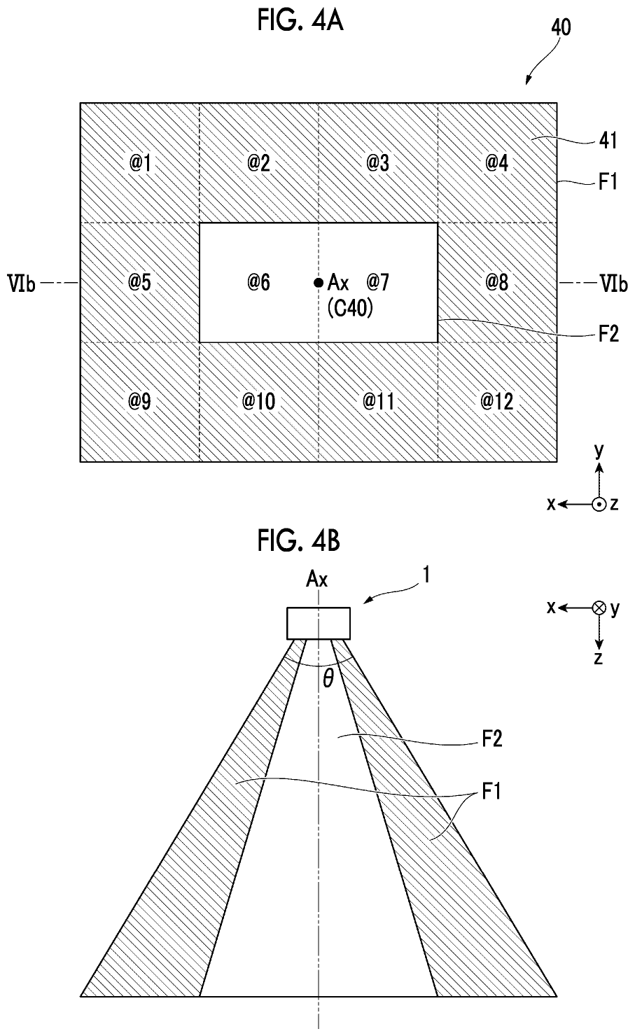

As shown in the drawing, the radiation plane 40 is divided into a plurality of radiation sections 41 corresponding to the light emitting sections 101 in the light emitting surface 100. In the example of FIG. 2, the radiation plane 40 is divided into 12 radiation sections 41 of four radiation sections 41 in the x direction and three radiation sections 41 in the y direction. In a case where there is no need to distinguish the radiation sections 41, the radiation sections 41 are distinguished as radiation sections @1 to @12 in order from an upper left side (an end in the +x direction and the +y direction) in FIGS. 4A and 4B.

A light emitting section #i given with the same number i as a certain radiation section @i is referred to as a “corresponding light emitting section”. For example, the light emitting section #1 is a light emitting section corresponding to the radiation section @1. On the contrary, a radiation section @i given with the same number as a certain light emitting section #i is referred to as a “corresponding radiation section”.

The radiation sections @1 to @12 have a surface-symmetrical arrangement to the light emitting sections #1 to #12 in terms of an xy plane. For example, with the light emitting sections #1, #2, #3, and #4 being arranged in this order in the −x direction, the radiation sections @1, @2, @3, and @4 are arranged in this order in the −x direction.

Then, light from the corresponding light emitting section 101 is radiated to the radiation section 41. In more detail, an amount of light radiated from the light emitting section #i corresponding to the certain radiation section @i is greater than an amount of light radiated from another light emitting section #j (i≠j).

Hereinafter, as indicated by a two-way arrow of FIG. 2, in the radiation plane 40, a direction from the outline of the radiation plane 40 toward the center C40 is an “inside”, and a direction from the center C40 toward the outline of the radiation plane 40 is an “outside”. In the light emitting surface 100, a direction from the outline of the light emitting surface 100 toward the center C100 is an “inside”, and a direction from the center C100 toward the outline of the light emitting surface 100 is an “outside”.

Light Emitting Unit 4

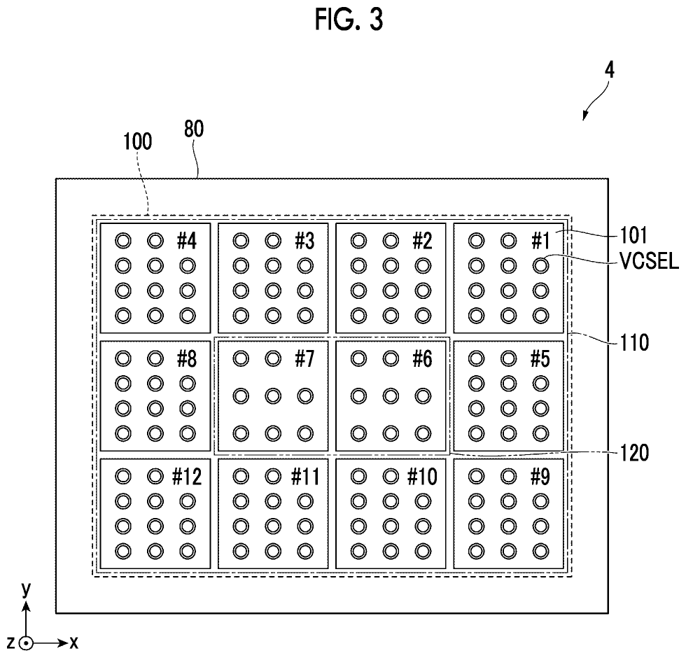

FIG. 3 is a diagram showing the light emitting unit 4 according to the first exemplary embodiment. FIG. 3 shows a state as viewed from a side on which the light emitting unit 4 radiates light. Accordingly, in FIG. 3, a right direction of the paper is the x direction, an upward direction of the paper is the y direction, and a front direction of the paper is the z direction. A plan view is a diagram as the light emitting unit 4 is viewed from the z direction side.

As shown in FIG. 3, the light emitting unit 4 has a substrate 80, and a light emitting surface 100 on which the VCSELs are disposed. In more detail, the substrate 80 and the light emitting surface 100 are provided to overlap each other in a direction (the +z direction or the front direction of the paper) in which light is radiated.

As in the example shown n FIG. 2, the light emitting unit 4 includes 12 light emitting sections 101 (light emitting sections #1 to #12) with the VCSELs arranged on the light emitting surface 100. In this example, all the light emitting sections #1 to #12 have the same area.

Then, in the example shown in FIG. 3, the number of VCSELs arranged in the light emitting sections #1 to #5 and #8 to #12 is greater than the number of VCSELs arranged in the light emitting sections #6 and 7. In more detail, 11 VCSELs are disposed in the light emitting sections #1 to #5 and #8 to #12, and eight VCSELs are disposed in the light emitting sections #6 and 7. That is, the number (density) of VCSELs per unit area in the light emitting sections #1 to #5 and #8 to #12 is greater than the number (density) of VCSELs per unit area in the light emitting sections #6 and #7.

Here, in the drive of each light emitting section 101, in a case where the same amount of power is supplied to all VCSELs, the greater the number of VCSELs per unit area, the greater the amount of light radiated from the light emitting section 101. In the example of FIG. 3, an amount of light radiated from a region 110 (in the drawing, one-dot chain line) composed of the light emitting sections #1 to #5 and 8 to #12 is greater than an amount of light radiated from a region 120 (in the drawing, two-dot chain line) composed of the light emitting sections #6 and #7. Here, the region 110 is an example of a first light emitting region. The region 120 is an example of a second light emitting region. Hereinafter, the regions 110 and 120 are described as light emitting regions 110 and 120.

In the example of FIG. 3, the light emitting region 110 is positioned outside the light emitting region 120. Here, the light emitting region 110 is provided to surround the outside of the light emitting region 120.

Light radiated from the light emitting unit 4 spreads to a plane perpendicular to a radiation direction (an axial direction of the central axis Ax) by an optical member (not shown) or the like and is radiated to the radiation plane 40. As the optical member, a diffusion plate that is provided on a path of light to diffuse light with scattering or the like, a diffractive optical element (DOE) or/and a lens that changes an angle of incident light and emits light, or the like can be used.

Light Radiated from Light Emitting Unit 4

Next, light radiated from the light emitting unit 4 according to the first exemplary embodiment will be described in more detail referring to FIGS. 2 to 4. In FIGS. 4A and 4B, a case where the light emitting unit 4 illustrated in FIGS. 2 and 3 is used will be described.

FIGS. 4A and 4B are diagrams illustrating an amount of light radiated to each radiation section 41, and specifically, FIG. 4A shows the radiation plane 40, and FIG. 4B is a sectional view taken along the line VIB-VIB of FIG. 4A. In FIG. 4B, a spread angle of light radiated from the ToF camera 1 is indicated by reference numeral θ.

To each radiation section 41, light is radiated from the corresponding light emitting section 101. Accordingly, the light from the light emitting region 110 in FIG. 3 is radiated to a radiation region F1 (a hatched portion of FIG. 4A) composed of the radiation sections @1 to @5 and @8 to @12. Light from the light emitting region 120 is radiated to a region F2 (an outlined portion of FIG. 4A) composed of the radiation sections @6 and @7. Hereinafter, the regions F1 and F2 are described as radiation regions F1 and F2.

In the example of FIGS. 4A and 4B, the radiation region F1 is positioned outside the radiation region F2. Here, the radiation region F1 is provided to surround the outside of the radiation region F2. Here, the radiation region F1 is an example of a first radiation region, and the radiation region F2 is an example of a second radiation region.

As described above, since the amount of light radiated from the light emitting region 110 is greater than the amount of light radiated from the light emitting region 120, an amount of light radiated to the radiation region F1 is greater than an amount of light radiated to the radiation region F2.

In the sectional view shown in FIG. 4B, the radiation region F1 is hatched, and the radiation region F2 is outlined. In the sectional view, the radiation region F1 is positioned outside the radiation region F2. That is, the radiation region F1 is at a position where the spread angle θ is greater than the radiation region F2.

In FIG. 4B, although the sectional view taken along the line VIB-VIB in FIG. 4A is shown, even in any cross section in an axial direction including the central axis Ax, the radiation region F1 is positioned outside the radiation region F2.

In this way, the light emitting unit 4 includes the light emitting region 120 that radiates light to the radiation region F2, and the light emitting region 110 that radiates light to the radiation region F1 positioned outside the radiation region F2, and the amount of light radiated from the light emitting region 110 to the radiation region F1 is greater than the amount of light radiated from the light emitting region 120 to the radiation region F2.

Additionally, the light emitting region 110 is provided to surround the light emitting region 120, whereby the radiation region F1 is positioned to surround the radiation region F2.

Measurement Distance of ToF Camera 1

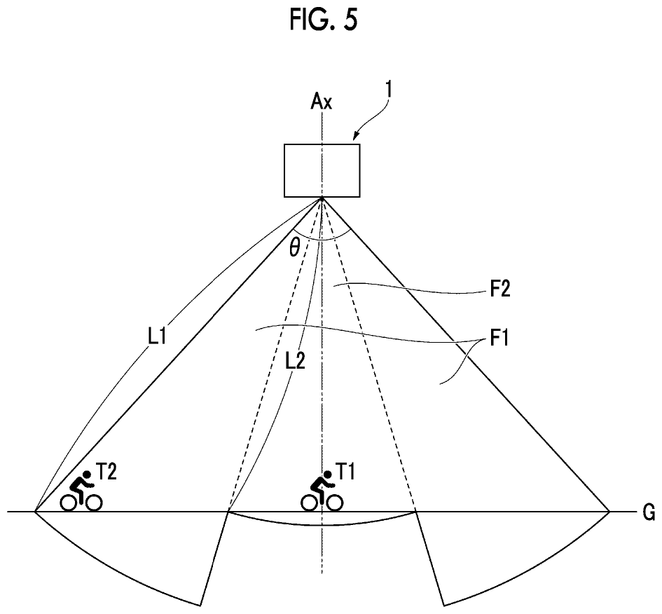

Next, a measurement distance of the ToF camera 1 to which the first exemplary embodiment is applied will be described referring to FIG. 5.

FIG. 5 is a diagram showing a measurement distance L1 in the radiation region F1 and a measurement distance L2 in the radiation region F2 in the ToF camera 1 to which the first exemplary embodiment is applied.

Reference numerals T1 and T2 in FIG. 5 are objects to be detected, and a straight line G is the ground.

As described above, as the amount of light (the amount of the measurement light) radiated from the light emitting unit 4 of the ToF camera 1 is greater, it is possible to secure necessary length measurement accuracy even at a position separated from the light emitting unit 4, and the measurement distance increases.

Accordingly, in the ToF camera 1, as shown in FIG. 5, the measurement distance L1 in the first radiation region F1 is longer than the measurement distance L2 in the second radiation region F2.

As a result, in the ToF camera 1, for not only the object T2 to be detected that has a distance from the ToF camera 1 equal to or less than the measurement distance L2, but also the object T2 to be detected that is positioned in a region where the spread angle θ is greater and has a distance from the ToF camera 1 equal to or more than the measurement distance L1 and equal to or less than the measurement distance L2, it is possible to perform measurement while securing required length measurement accuracy.

In the first exemplary embodiment described above, the light emitting regions 110 and 120 composed of a plurality of light emitting sections 101 have been described as an example of a first light emitting region and a second light emitting region, respectively. Here, each light emitting section 101 configuring the light emitting region 110 may be regarded as an example of a first light emitting region, and each light emitting section 101 configuring the light emitting region 120 may be regarded as an example of a second light emitting region. That is, any one of the light emitting sections #1 to #5 and #8 to #12 may be regarded as an example of a first light emitting region, and any one of the light emitting sections #6 and #7 may be regarded as an example of a second light emitting region.

Similarly, in regards to a first radiation region and a second radiation region, each radiation section 41 configuring the radiation region F1 can be regarded as an example of a first radiation region, and each radiation section 41 configuring the radiation region F2 can be regarded as an example of a second radiation region. That is, any one of the radiation sections @1 to @5 and @8 to @12 may be regarded as an example of a first radiation region, and any one of the radiation sections @6 and @7 may be regarded as an example of a second radiation region.

### COMPARATIVE EXAMPLE

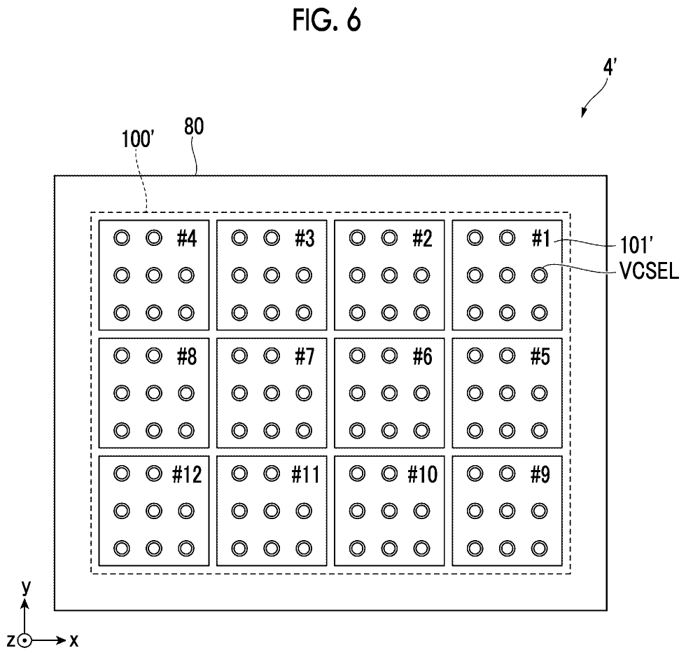

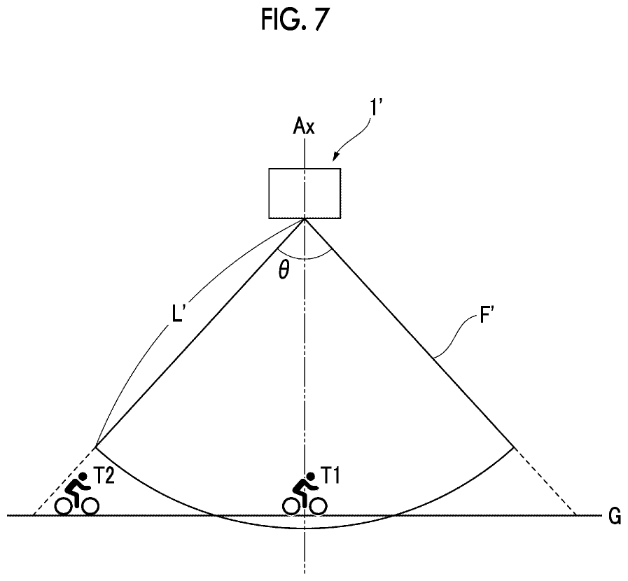

Next, a ToF camera 1′ to which the first exemplary embodiment is not applied, for comparison will be described referring to FIGS. 6 and 7. The ToF camera 1′ to which the first exemplary embodiment is not applied is referred to as “a ToF camera 1′ of the related art”.

FIG. 6 is a diagram illustrating a light emitting unit 4′ of the ToF camera 1′ to which the first exemplary embodiment is not applied, for comparison.

The ToF camera 1′ of the related art is different from the ToF camera 1 to which the first exemplary embodiment is applied, only in the arrangement of VCSELs on a light emitting surface 100′ of the light emitting unit 4′. In more detail, all light emitting sections 101′ on the light emitting surface 100′ have the same number of VCSELs. Specifically, eight VCSELs are disposed in all light emitting sections 101′.

Accordingly, in a case where the same amount of power is supplied to all VCSELs, the amount of light radiated from each light emitting section 101′ is equal. That is, the ToF camera 1′ of the related art radiates light to the radiation plane uniformly. In more detail, the ToF camera 1′ of the related art radiates the same amount of light to all radiation sections corresponding to the light emitting sections #1 to #12. A region composed of all radiation sections in the ToF camera 1′ of the related art is described as a radiation region F′.

FIG. 7 is a diagram showing a measurement distance L′ of the ToF camera 1′ to which the first exemplary embodiment is not applied, for comparison.

As described referring to FIG. 6, the ToF camera 1′ of the related art radiates light to the radiation region F′ uniformly. Accordingly, the ToF camera 1′ of the related art has a uniform measurement distance L′ in the radiation region F′. In more detail, the measurement distance L′ is uniform in an outside region where the spread angle θ is great and an inside region where the spread angle θ is small.

As a result, in the ToF camera 1′ of the related art, while it is possible to perform measurement for the object T1 to be detected that has the distance from the ToF camera 1′ equal to or less than the measurement distance L′, for the object T2 to be detected that is positioned in a region where the spread angle θ is greater and has the distance from the ToF camera 1′ equal to or more than the measurement distance L′, length measurement accuracy does not meet the requirement, and measurement is hardly performed.

In the ToF camera 1′ of the related art illustrated in FIG. 6, since the eight VCSELs are disposed in all light emitting sections 101′, the measurement distance L′ is equal to the measurement distance L2 (see FIG. 5). That is, a magnitude relationship between the measurement distances L1 and L2 in the ToF camera 1 and measurement distance L′ in the ToF camera 1′ of the related art is L′=L2<L1.

Additionally, as shown in FIGS. 5 and 7, in the ToF camera 1, the ground G can be detected even in a region where the spread angle θ is large; however, in the ToF camera 1′ of the related art, the ground G is hardly detected in a region where the spread angle θ is large.

In this way, in the ToF camera 1, the light emitting unit 4 has the light emitting region 110 and the light emitting region 120, the amount of light radiated from the light emitting region 110 to the radiation region F1 is greater than the amount of light radiated from the light emitting region 120 to the radiation region F2, and the radiation region F1 is positioned outside with respect to the radiation region F2, whereby the measurement distance in the region where the spread angle θ is large is extended compared to the ToF camera 1′ of the related art that radiates light uniformly.

In the ToF camera 1′ of the related art, a configuration in which the number of VCSELs per unit area increases in all light emitting sections 101′ is considered for the purpose of extending the measurement distance L′ uniformly. That is, a configuration in which each light emitting section 101′ has 11 VCSELs to increase the amount of radiated light uniformly is also considered. In this case, in the inside region where the spread angle θ is small, a distance from the ToF camera 1′ to the ground G is small, and even though necessary measurement distance L′ is small, an extremely large measurement distance L′ is secured. That is, power consumption related to the drive of the VCSELs is extremely large.

In contrast, in the ToF camera 1 to which the first exemplary embodiment is applied, since only the number of VCSELs per unit area in the first light emitting region is increased, power consumption related to the drive of the VCSELs is reduced compared to the ToF camera 1′ of the related art.

### Second Exemplary Embodiment

A second exemplary embodiment is different from the first exemplary embodiment only in the configuration of the light emitting unit.

In the light emitting unit according to the first exemplary embodiment, the number of VCSELs per unit area in the first light emitting region is greater than the number of VCSELs per unit area in the second light emitting region, thereby making the amount of light radiated from the first light emitting region greater than the amount of light radiated from the second light emitting region. In a light emitting unit according to the second exemplary embodiment, an area of a light emitting section belonging to a first light emitting region is smaller than an area of a light emitting section belonging to a second light emitting region.

Other configurations are the same as the configurations in the first exemplary embodiment, and description thereof will not be repeated. Description will be provided only for the light emitting unit that is a different portion. The same portions as the portions in the first exemplary embodiment are represented by the same reference numerals, and description thereof will not be repeated.

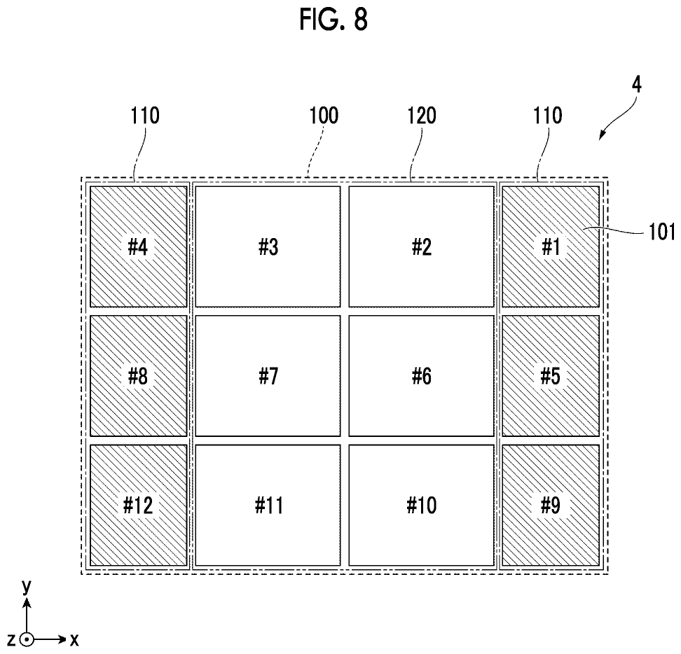

FIG. 8 is a diagram illustrating a light emitting unit 4 according to the second exemplary embodiment. In FIG. 8, only the appearance of a light emitting section 101 is described and other configurations are omitted. FIG. 8 shows a state as the light emitting unit 4 is viewed from a side on which light is radiated. Accordingly, in FIG. 8, a right direction of the paper is the x direction, an upward direction of the paper is the y direction, and a front direction of the paper is the z direction.

In the example of FIG. 8, an area of a hatched light emitting section #1, #4, #5, #8, #9, or #12 is smaller than an area of an outlined light emitting section #2, #3, #6, #7, #10, or #11.

In the light emitting unit 4, in a case where the amount of power supplied to each light emitting section 101 is equal, the smaller the area of the light emitting section 101, the greater the amount of power supplied per unit area and the greater the amount of radiated light. Accordingly, the amount of light radiated from the light emitting section #1, #4, #5, #8, #9, or #12 is greater than the amount of light radiated from the light emitting section #2, #3, #6, #7, #10, or #11.

Here, regions 110 composed of the light emitting sections #1, #4, #5, #8, #9, and #12 are an example of a first light emitting region. A region 120 composed of the light emitting sections #2, #3, #6, #7, #10, and #11 is an example of a second light emitting region.

In FIG. 8, the light emitting regions 110 are provided outside the light emitting region 120. In more detail, the light emitting regions 110 are provided on both sides (a right-left direction of the drawing) of the light emitting region 120 in the ±x direction.

Then, with the light emitting region 110 being provided on both sides of the light emitting region 120, regions (an example of a first radiation region) to which light from the light emitting region 110 is radiated are positioned on both sides of a region (an example of a second radiation region) to which light from the light emitting region 120 is radiated.

In the example of FIG. 8, the light emitting section 101 belonging to the light emitting region 110 has a width in the x direction (the right-left direction of the drawing) smaller than the light emitting section 101 belonging to the light emitting region 120, and has a small area. A method of decreasing the area of the light emitting section 101 belonging to the light emitting region 110 small is not limited, and a width in the y direction may be decreased or both the width in the x direction and the width in the y direction may be decreased.

### Third Exemplary Embodiment

In a third exemplary embodiment, an amount of power supplied to each light emitting section is made different, whereby an amount of light radiated from a first light emitting region is greater than an amount of light radiated from a second light emitting region. Here, the third exemplary embodiment will be described using a case where the amount of power supplied to each light emitting section 101 is made different in the light emitting unit 4 of FIGS. 2 to 4, as an example.

As shown in Expression (4), an amount Wh of power supplied to the light emitting section 101 is a product of a voltage V that is applied to the light emitting section 101, a current I, and an application time t.

Wh=V·I·t (4)

Then, in the third exemplary embodiment, the drive unit 6 controls the voltage V, the current I, and the application time t, thereby making the amount of power to supplied to the light emitting section 101 belonging to the light emitting region 110 greater than the amount of power supplied to the light emitting section 101 belonging to the light emitting region 120. As a result, even in the light emitting unit 4 to which the third exemplary embodiment is applied, the amount of light radiated from the light emitting region 110 is greater than the amount of light radiated from the light emitting region 120.

### Fourth Exemplary Embodiment

In a fourth exemplary embodiment, an optical member that changes a path of light radiated from the VCSEL is provided. The fourth exemplary embodiment is different from the first exemplary embodiment in that the optical member is provided such that an amount of light radiated from a first light emitting region is greater than an amount of light radiated from a second light emitting region.

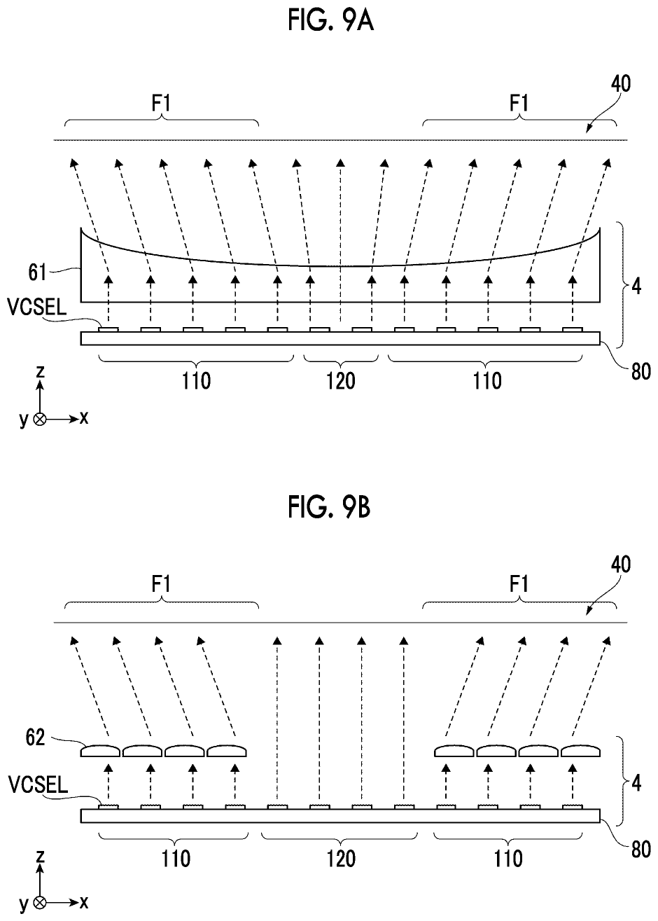

FIGS. 9A and 9B are diagrams showing an example of a light emitting unit 4 according to the fourth exemplary embodiment, and specifically, FIG. 9A shows an example of a case where one lens 61 is used, and FIG. 9B shows an example of a case where a lens 62 is provided corresponding to each VCSEL. In FIGS. 9A and 9B, an upward direction of the paper is the z direction, a right direction of the paper is the x direction, and a back direction of the paper is the y direction. Only the VCSELs, the substrate 80, and the lens 61 or the lens 62 in the light emitting unit 4 are described, and other configurations are omitted.

In the examples shown in FIGS. 9A and 9B, the number of VCSELs per unit area is constant over the entire light emitting surface 100.

In the example of FIG. 9A, one lens 61 that covers all VCSELs disposed in the light emitting unit 4 is provided. The lens 61 is held to be positioned away from the VCSELs by a holding member (not shown) provided on the substrate 80.

The lens 61 is a concave lens or a plano-concave lens in which at least a surface (+z direction side or an upper side of the paper in FIG. 9A) in a radiation direction of light has a concave shape.

The lens 61 changes a path of light from the VCSEL disposed in the light emitting unit 4 to the outside in the ±x direction (the right-left direction of the paper) on the radiation plane 40 as indicated by a broken-line arrow in the drawings and radiates light. As a result, the amount of light that is radiated to the radiation region F1 positioned outside in the radiation plane 40 increases.

In the example of FIG. 9B, the lens 62 corresponding to each VCSEL positioned on the outside (the right-left direction of the paper) in the ±x direction in the light emitting unit 4 is provided. The lens 62 is a convex lens or a plano-convex lens in which at least a surface (+z direction side, an upper side of the paper in FIG. 9B) in a radiation direction of light has a convex shape, and shifts an optical axis with respect to the VCSEL.

The lens 62 changes a path of light radiated from the corresponding VCSEL as indicated by a broken-line arrow in the drawing and radiates light to the radiation region F1.

Here, as shown in FIGS. 9A and 9B, in the light emitting unit 4, a region where the VCSEL that radiates light to the radiation region F1 is disposed is referred to as the light emitting region 110. In more detail, the VCSEL disposed in the light emitting region 110 radiates light to the radiation region F1 as a result of the path of light being changed by the lens 61 or 62. A region where another VCSEL is disposed is referred to as the light emitting region 120.

The lens 61 and the lens 62 are provided such that the amount of light radiated from the light emitting region 110 is greater than the amount of light radiated from the light emitting region 120.

For example, in the example of FIG. 9A, the lens 61 is designed such that the number of VCSELs that radiate light to the radiation region F1 is greater than the number of VCSELs that radiate light to another region.

For example, in the example of FIG. 9B, the number of VCSELs to which the corresponding lens 62 is provided is greater than the number of VCSELs to which the lens 62 is not provided.

In the examples of FIGS. 9A and 9B, the light emitting region 110 is an example of a first light emitting region, and the light emitting region 120 is an example of a second light emitting region.

The lenses 61 and 62 in FIGS. 9A and 9B are an example of an optical member.

In the fourth exemplary embodiment, the optical member may have any shape or any arrangement as long as the amount of light radiated from the first light emitting region is greater than the amount of light radiated from the second light emitting region, and is not limited to the lenses 61 and 62 shown in FIGS. 9A and 9B.

### Fifth Exemplary Embodiment

In a fifth exemplary embodiment, the magnitude of a current supplied to each light emitting section is made different, whereby an amount of light radiated from a first light emitting region is greater than an amount of light radiated from a second light emitting region.

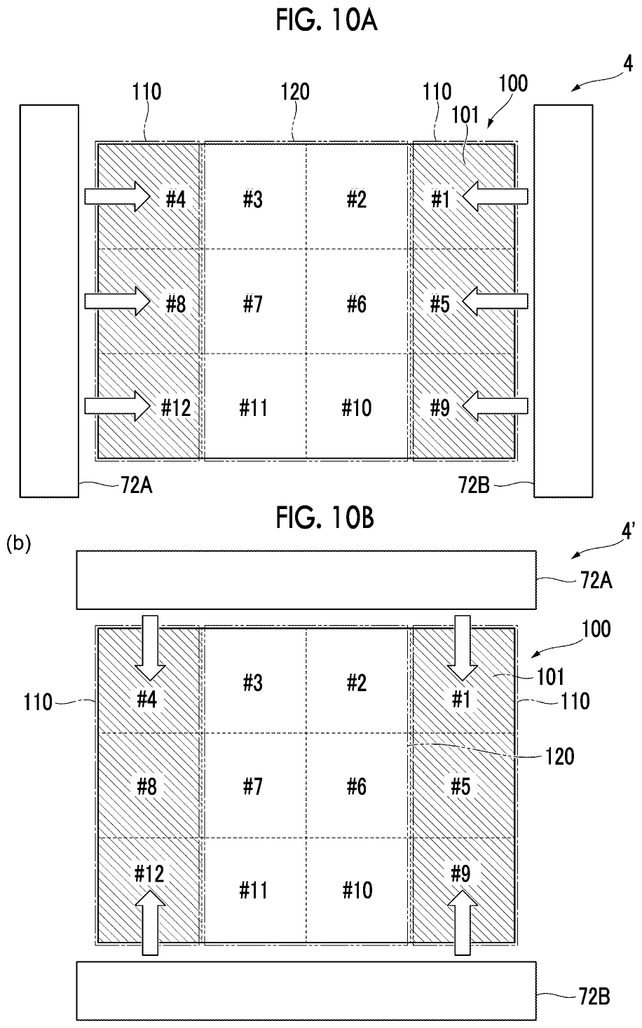

FIGS. 10A and 10B are diagrams illustrating a light emitting unit 4 according to the fifth exemplary embodiment, and specifically, FIG. 10A shows an example of a light emitting unit 4 to which the fifth exemplary embodiment is applied, and FIG. 10B shows a light emitting unit 4′ to which the fifth exemplary embodiment is not applied, for comparison.

In FIGS. 10A and 10B, description will be provided using a case where light emitting regions 110 that are an example of a first light emitting region are provided on both sides of a light emitting region 120 that is an example of a second light emitting region. In more detail, description will be provided using a case where the light emitting regions 110 composed of light emitting sections #1, #4, #5, #8, #9, and #12 and the light emitting region 120 composed of light emitting sections #2, #3, #6, #7, #10, and #11, and an amount of light radiated from the light emitting regions 110 is greater than an amount of light radiated from the light emitting region 120.

Pad parts 72A and 72B are an example of an electrode that is provided to supply a current to the light emitting unit 4, and the pad parts 72A and 72B and each light emitting section 101 are connected by pointing wires (not shown) to be a path of a current. In more detail, the current from the pad parts 72A and 72B is supplied to each light emitting section 101 via the pointing wires.

In the light emitting unit 4, the current more easily flows in the light emitting sections 101 close to the pad parts 72A and 72B than the light emitting section 101 away from the pad parts 72A and 72B. Then, the amount of light radiated from the light emitting section 101 increases following the flowing current.

As shown in FIG. 10A, the pad parts 72A and 72B are provided along the light emitting regions 110, whereby the current more easily flows in the light emitting regions 110 than the light emitting region 120, and the amount of light radiated from the light emitting regions 110 is greater than the amount of light radiated from the light emitting region 120.

Here, in the example of FIG. 10A, the pointing wires that connect the pad parts 72A and 72B and the light emitting section 101 belonging to the light emitting region 110 are an example of a current supply path through which the current is supplied along the light emitting regions 110.

On the other hand, as shown in FIG. 10B, in a case where the pad parts 72A and 72B are provided without following the light emitting regions 110, the current hardly flows in a part (in this example, the light emitting sections #5 and #8) of the light emitting regions 110, and the amount of light radiated from the light emitting region 110 decreases compared to the example of the FIG. 10A.

In this way, in the fifth exemplary embodiment, in a case where the first light emitting region is provided on one side or both sides of the second light emitting region, the electrode is provided along the first light emitting region, and the current supply path through which the current is supplied along the first light emitting region is provided, whereby the amount of light radiated from the first light emitting region is greater than the amount of light radiated from the second light emitting region.

In the first to fifth exemplary embodiments described above, description has been provided using any one of a configuration in which the first light emitting region is provided to surround the second light emitting region or a configuration in which the first light emitting region is provided on one side or both sides of the second light emitting region, as an example. Among the exemplary embodiments, in the first to fourth exemplary embodiments, the arrangement of the first light emitting region and the second light emitting region is not limited, and the first radiation region to which light from the first light emitting region is radiated may be positioned outside the second radiation region to which light from the second light emitting region is radiated.

In the second to fifth exemplary embodiments described above, the number of VCSELs per unit area in the first light emitting region may be greater than or equal to the number of VCSELs per unit area in the second light emitting region.

That is, as long as the amount of light radiated from the first light emitting region is greater than the amount of light radiated from the second light emitting region, the number of VCSELs per unit area is not limited.

### APPLICATION EXAMPLES AND MODIFICATION EXAMPLES

Third Light Emitting Region

Here, although a case where all light emitting sections in the light emitting unit are made to emit light has been described as an example, in using the detection apparatus, the detection apparatus may be used while a part of light emitting sections is not made to emit light (not driven).

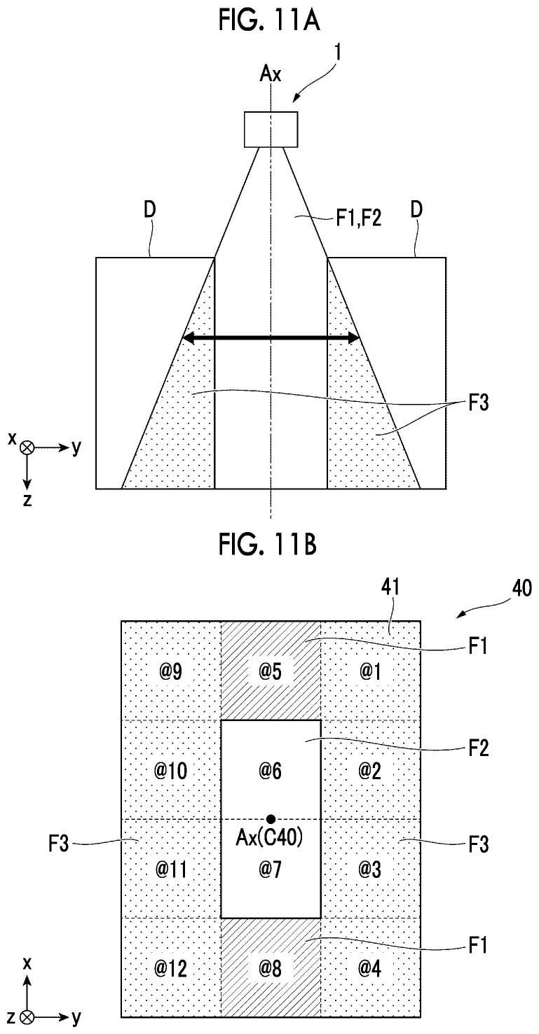

First to third application examples where the detection apparatus is used while a part of light emitting sections is not made to emit light will be described referring to FIGS. 11 to 13.

In the first application example, a case where the ToF camera 1 (see FIGS. 1 to 4) to which the first exemplary embodiment is applied is used in a store will be described as an example. In the first application example, the arrangement of the light emitting regions 110 and 120 in the light emitting unit 4 and the radiation regions F1 and F2 in the radiation plane 40 are the same as the arrangements shown in FIGS. 2 to 4B.

The ToF camera 1 is installed in, for example, an unmanned store, and performs detection of a visitor or detection of an article picked up by the visitor.

FIGS. 11A and 11B are diagrams illustrating the first application example, and specifically, FIG. 11A shows an example where the ToF camera 1 to which the first exemplary embodiment is applied is installed on a ceiling of a passage provided between two rows of display racks D, and FIG. 11B shows a radiation plane 40 at a position of a two-way arrow of FIG. 11A.

Ina store, a passage provided between two rows of display racks D arranged to face each other may be a target to be detected of the ToF camera 1. In this case, for example, as shown in FIG. 11A, the ToF camera 1 is installed on a ceiling of the passage and perform detection from an upper side of the two rows of display racks D.

In the example of FIGS. 11A and 11B, the two rows of display racks D are arranged in the y direction, and the ToF camera 1 installed on the ceiling in the −z direction with respect to the display racks D has the passage extending in the ±x direction between the two rows of display racks D as a target to be detected.

In the example of FIG. 11A, since the display racks D are disposed in regions F3 positioned outside in the ±y direction with respect to a radiation region F1 and a radiation region F2, the regions F3 may be excluded from a target to be detected. Accordingly, the light emitting unit 4 (see FIG. 3) of the ToF camera 1 does not need to radiate light to the regions F3.

Here, as shown in FIG. 11B, in a case where the regions F3 match radiation sections @1 to @4 and @9 to @12, the regions F3 are an example of a third radiation region that shares a part of a region with the radiation regions F1. In this case, the drive unit 6 does not make corresponding light emitting sections #1 to #4 and #9 to #12 (see FIG. 3) emit light.

In this case, the regions F3 are an example of a third radiation region and share a part of a region with the radiation regions F1. Then, a region composed of the light emitting sections #9 to #12 is an example of a third light emitting region and shares a part of the light emitting sections 101 with the light emitting region 110.

In a second application example, a case where the ToF camera 1 (see FIGS. 1 to 4B) to which the first exemplary embodiment is applied is installed on a wall in a store will be described as an example. In the second application example, the arrangement of the light emitting regions 110 and 120 in the light emitting unit 4 and the arrangement of the radiation regions F1 and F2 in the radiation plane 40 are the same as the arrangements shown in FIGS. 2 to 4B.

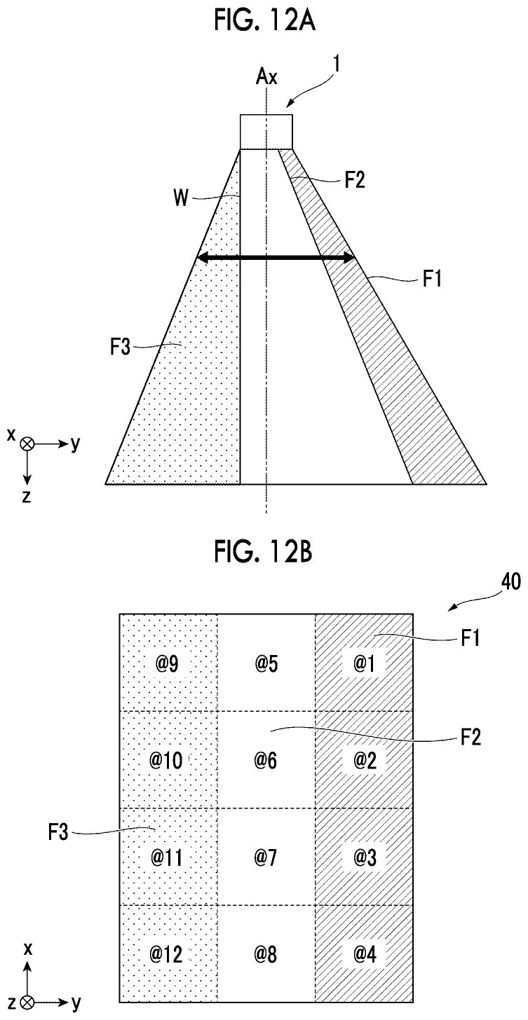

FIGS. 12A and 12B are diagrams illustrating the second application example, and specifically, FIG. 12A shows an example of a case where the ToF camera 1 is installed on a wall surface W, and FIG. 12B shows a radiation plane 40 at a position of a two-way arrow of FIG. 12A.

In the example of FIG. 12A, since the wall surface W is present in a region F3 positioned outside in the −y direction with respect to a radiation region F1 and a radiation region F2, the region F3 may be excluded from a target to be detected. Accordingly, the light emitting unit 4 (see FIG. 3) of the ToF camera 1 does not need to radiate light to the regions F3. As shown in FIG. 12B, in a case where the region F3 matches the radiation sections @9 to @12, the drive unit 6 does not make corresponding light emitting sections #9 to #12 (see FIG. 3) emit light.

In this case, the regions F3 are an example of a third radiation region and share apart of a region with the radiation regions F1. Then, a region composed of the light emitting sections #9 to #12 is an example of a third light emitting region and shares a part of the light emitting sections 101 with the light emitting region 110.

In a third application example, a case where the ToF camera 1 is mounted in an automobile has been described as an example.

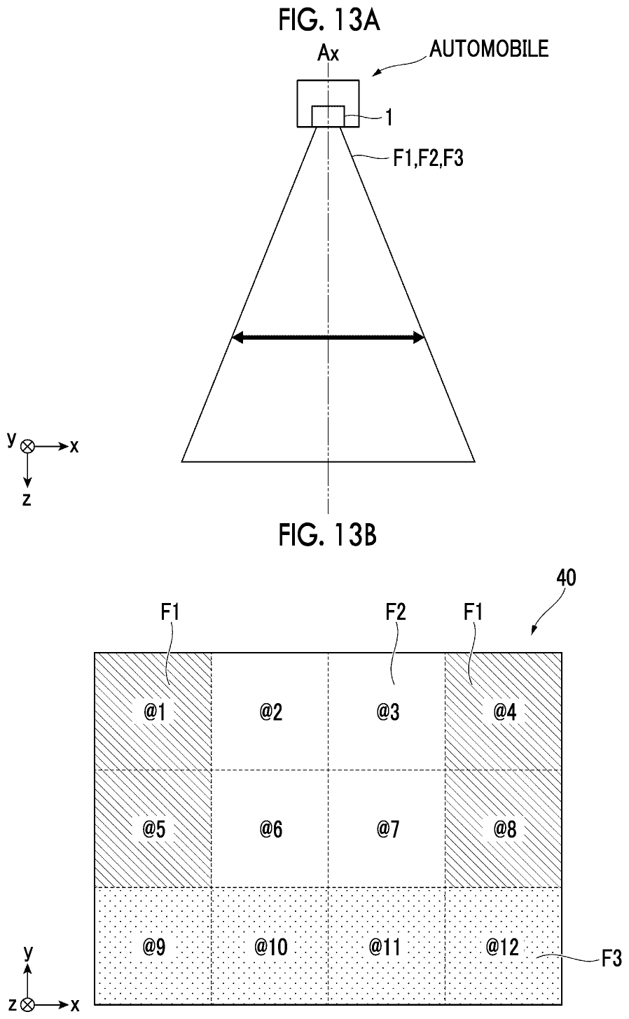

FIGS. 13A and 13B are diagrams illustrating the third application example, and specifically, FIG. 13A shows an example of a case where the ToF camera 1 is mounted in an automobile, and FIG. 13B shows a radiation plane 40 in the example of FIG. 13A. FIG. 13A shows a scene as the automobile is viewed from an upper side. That is, a road surface is present in the −z direction. It is assumed that the automobile is moving toward the +z direction. FIG. 13B corresponds to the radiation plane 40 at a position of a two-way arrow of FIG. 13A.

As shown in FIG. 13A, in a case where the ToF camera 1 is mounted in the automobile, for example, the ToF camera 1 radiates light towards a moving direction (+z direction) of the automobile and detects an obstacle or an inter-vehicle distance in the moving direction. In this case, the measurement distance may be extended only as viewed from the automobile (±x direction).

Accordingly, a case where radiation sections @1, @4, @5, @8, @9, and @12 on both sides in the ±x direction on the radiation plane 40 shown in FIG. 13B are set as a radiation region F1, radiation sections @2, @3, @6, @7, @10, and @11 on the inside in the x direction are set as a radiation region F2, and an amount of light that is radiated to the radiation region F1 is greater than an amount of light that is radiated to the radiation region F2 is considered. That is, a case where, in the light emitting unit 4, the amount of light radiated from the light emitting section #1, #4, #5, #8, #9, or #12 is greater than the amount of light radiated from the light emitting section #2, #3, #6, #7, #10, or #11 is considered.

In this case, the radiation region F1 is an example of a first radiation region, and the radiation region F2 is an example of a second radiation region. In the light emitting unit 4, regions composed of the light emitting sections #1, #4, #5, #8, #9, and #12 are an example of a first light emitting region, and a region composed of the light emitting sections #2, #3, #6, #7, #10, and #11 is an example of a second light emitting region.

Here, since the road surface is present in the −z direction of the automobile, a region F3 may be excluded from a target to be detected. That is, as shown in FIG. 13B, radiation of light to the radiation sections @9 to @12 on the −y direction side of the radiation plane 40 is not needed. Accordingly, the drive unit 6 does not make corresponding light emitting sections #9 to #12 emit light.

In this case, the region F3 composed of the radiation sections @9 to @12 is an example of a third radiation region, and shares a part of a region with the radiation regions F1 and the radiation region F2. The region composed of the light emitting sections #9 to #12 is an example of a third light emitting region and shares apart of the light emitting sections 101 with the regions composed of the light emitting sections #1, #4, #5, #8, #9, and #12 and the region composed of the light emitting sections #2, #3, #6, #7, #10, and #11.

As in the first to third application examples described above, in the detection apparatus to which the first to fifth exemplary embodiment are applied, the third light emitting region that is a light emitting region sharing at least a part of the light emitting sections with the first light emitting region and/or the second light emitting region and radiates light to the third radiation region is provided, and in a case where radiation of light to the third radiation region is not needed, it is possible to perform measurement without making the light emitting sections configuring the third light emitting region emit light.

With this configuration, power consumption related to the drive of the VCSELs is reduced compared to a case where light is constantly radiated to the third radiation region. The occurrence of multipath noise due to display racks, a wall surface, a road surface, or the like is suppressed, and length measurement accuracy is improved compared to a case where light is radiated to the third radiation region.

Batch Drive of Light Emitting Surface 100

In the first to fifth exemplary embodiments described above, a case where the light emitting unit 4 is driven individually for each light emitting section 101 has been described as an example. In the first and fourth exemplary embodiments, the light emitting unit 4 may be driven in a batch. That is, all VCSELs disposed in the light emitting unit 4 may be driven in a batch.

For example, in the first exemplary embodiment, even in a case where all VCSELs disposed in the light emitting unit 4 are driven in a batch, in a case where the number of VCSELs per unit area in the light emitting region 110 is greater than the number of VCSELs per unit area in the light emitting region 120, the amount of light radiated from the light emitting region 110 is greater than the amount of light radiated from the light emitting region 120.

Note that the light emitting unit 4 can be driven individually for each light emitting section 101, control related to the third light emitting region as in the first to third application examples, control for making the amount of power supplied to each light emitting section 101 different as in the third exemplary embodiment, or the like easily performed compared to a configuration in which all VCSELs are driven in a batch.

Drive of Each Light Emitting Region

In the first, second, fourth, and fifth exemplary embodiments, the light emitting region 110 and the light emitting region 120 may be driven individually. In other words, each light emitting section may be driven individually in such a manner that the entire first light emitting region may be driven as one light emitting section, and the entire second light emitting region may be driven as one light emitting section.

Light Emitting Element

In the first to fifth exemplary embodiments, although an example where the VCSEL is used as an example of a light emitting element has been described, a light emitting diode (LED), a laser diode (LD), or the like may be used instead of the VCSEL.

Although an example of a case where a two-dimensional array is configured in which the VCSELs are arranged in two direction (x direction and y direction) has been described, a one-dimensional array may be configured in which the VCSELS are arranged in one direction. Even in the one-dimensional array, the first light emitting region and the second light emitting region may be provided with a direction toward one end or both ends in the arrangement of the VCSELs as an “outside” and a direction toward the center as an “inside”.

System Configured of Plurality of ToF Cameras 1

In a case of performing detection for a wide space, such as a store, a detection system with a plurality of ToF cameras 1 may be constructed.

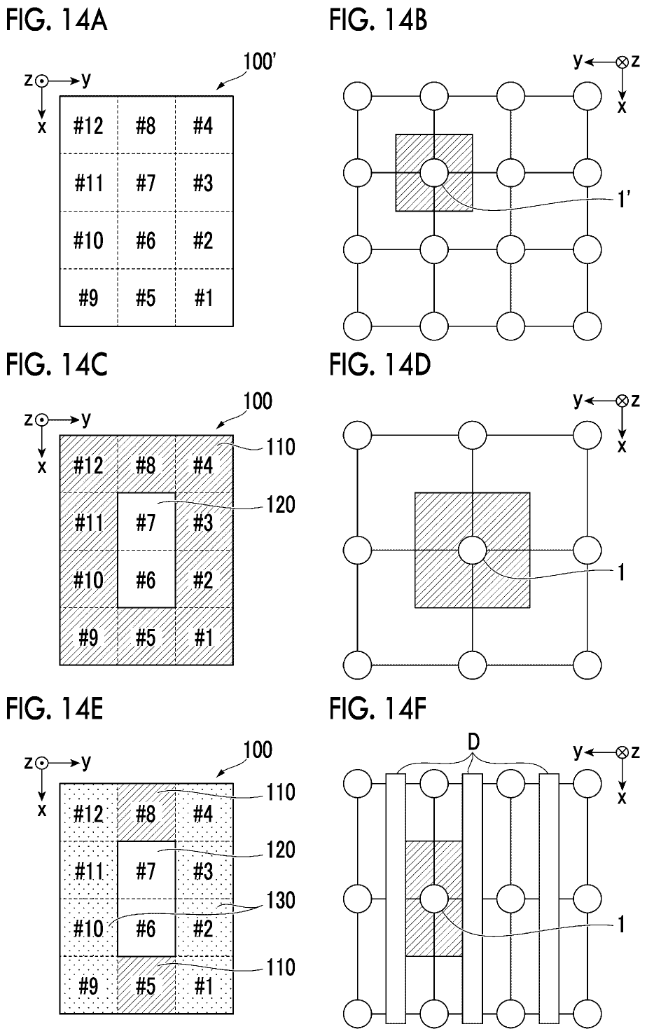

FIGS. 14A to 14F are diagrams illustrating a detection system with a plurality of ToF cameras 1, and specifically, FIG. 14A shows a light emitting surface 100′ in a ToF camera 1′ of the related art for comparison, FIG. 14B shows an example of a detection system with the ToF cameras 1′ of the related art of FIG. 14A, FIG. 14C shows the light emitting surface 100 in the ToF camera 1, FIG. 14D shows an example of a detection system with the ToF cameras 1 of FIG. 14C, FIG. 14E shows a light emitting surface 100 in another ToF camera 1, and FIG. 14F shows an example of a detection system with the ToF cameras 1 of FIG. 14E. The same portions as the portions in FIGS. 1 to 13B are represented by the same reference numerals, and description thereof will not be repeated.

FIGS. 14A to 14F shows an example of a case of performing detection for the entire space having the same size.

In FIGS. 14A, 14C, and 14E, an amount of light radiated from a hatched light emitting section is greater than an amount of light radiated from an outlined light emitting region. A dotted light emitting section does not emit light.

A plurality of circles in FIGS. 14B, 14D, and 14F indicate the ToF cameras 1 or 1′, and a hatched region indicates the spread of a measurement distance by the ToF camera 1 or 1′ at the center of the region.

As shown in FIG. 14A, in the ToF camera 1′ of the related art, the entire light emitting surface 100′ radiates light with the same amount of light uniformly. In a case where detection is possible for the hatched region in FIG. 14B with one ToF camera 1′ of the related art, to detect the entire space substantially with no gap, there is a need to dispose 16. ToF cameras 1′ of the related art.

On the other hand, in the ToF camera 1 shown in FIG. 14C, the amount of light radiated from hatched light emitting sections #1 to #5 and #8 to #12 is greater than the amount of light radiated from the light emitting sections #6 and #7. That is, the light emitting region 110 composed of the light emitting sections #1 to #5 and #8 to #12 is provided to surround the light emitting region 120 composed of the light emitting sections #6 and #7, and the amount of light radiated from the light emitting region 110 is greater than the amount of light radiated from the light emitting region 120.

In this case, as shown in FIG. 14D, the measurement distance of the ToF camera 1 is expanded toward a peripheral portion compared to the ToF camera 1′ of the related art. As a result, it is possible to increase an interval between a certain ToF camera 1 and an adjacent ToF camera 1, and the number of ToF cameras 1 to be installed is reduced compared to a case where the ToF camera 1′ of the related art is used.

In the ToF camera 1 shown in FIG. 14E, an amount of light radiated from hatched light emitting section #5 and #8 is greater than an amount of light radiated from light emitting sections s #6 and #7. That is, light emitting regions 110 composed of the light emitting sections #5 and #8 are provided on both sides in the ±x direction of a light emitting region 120 composed of light emitting sections #6 and #7, and an amount of light radiated from the light emitting regions 110 is greater than an amount of light radiated from the light emitting region 120.

As shown in FIG. 14F, the ToF camera 1 shown in FIG. 14E is installed on a ceiling of a passage provided between two rows of display racks D arranged in the y direction. In this case, since the display racks D are present in the ±y direction with respect to the ToF camera 1, corresponding regions may be excluded from a target to be detected. Accordingly, as shown in FIG. 14E, light emitting sections #1 to #4 and #9 to #12 positioned on both sides in the ±y direction do not radiate light. Regions 130 composed of the light emitting sections #1 to #4 and #9 to #12 are an example of a third light emitting region.

In this case, as shown in FIG. 14F, the measurement distance of the ToF camera 1 is expanded toward the ±x direction (an up-down direction of the drawing) compared to the ToF camera 1′ of the related art. As a result, an interval between a certain ToF camera 1 and an adjacent ToF camera 1 in the ±x direction (the up-down direction of the drawing) can be greater than an interval between the certain ToF camera 1 and an adjacent ToF cameras 1 in the ±y direction (a right-left direction of the drawing). That is, in this example, it is possible to increase the interval in the direction of the passage.

In this way, in the detection system using a plurality of ToF cameras 1, an interval between one ToF camera 1 and another adjacent ToF camera 1 can be greater in a direction in which the light emitting regions 110 are positioned in one ToF camera 1 than in a direction in which the light emitting region 120 is positioned.

Although the present exemplary embodiments have been described, the present invention is not limited to the present exemplary embodiments described above. The effects of the present invention are not limited to the effects described in the present exemplary embodiments describe above.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A detection apparatus comprising:
a light emitting unit including a first light emitting region that has at least one light emitting element and radiates light to a first radiation region and a second light emitting region that has at least one light emitting element and radiates light to a second radiation region;
a drive unit that drives the light emitting unit; and
a detection unit that detects an object based on a time until light radiated from the light emitting unit is reflected by the object and is received,
wherein the first radiation region is positioned outside with respect to the second radiation region, and
an amount of light radiated from the first light emitting region is greater than an amount of light radiated from the second light emitting region.

2. The detection apparatus according to claim 1,
wherein, in the light emitting unit, the first light emitting region is positioned outside with respect to the second light emitting region.

3. The detection apparatus according to claim 2,
wherein the first light emitting region is provided on one side or both sides of the second light emitting region.

4. The detection apparatus according to claim 2,
wherein the first light emitting region is provided to surround the second light emitting region.

5. The detection apparatus according to claim 1,
wherein the number of light emitting elements per unit area in the first light emitting region is greater than the number of light emitting elements per unit area in the second light emitting region.

6. The detection apparatus according to claim 2,
wherein the number of light emitting elements per unit area in the first light emitting region is greater than the number of light emitting elements per unit area in the second light emitting region.

7. The detection apparatus according to claim 3,
wherein the number of light emitting elements per unit area in the first light emitting region is greater than the number of light emitting elements per unit area in the second light emitting region.

8. The detection apparatus according to claim 4,
wherein the number of light emitting elements per unit area in the first light emitting region is greater than the number of light emitting elements per unit area in the second light emitting region.

9. The detection apparatus according to claim 1,
wherein each of the first light emitting region and the second light emitting region is divided into a plurality of light emitting sections having at least one light emitting element,
the drive unit makes each of the plurality of light emitting sections emit light independently, and
an area of the light emitting section belonging to the first light emitting region is smaller than an area of the light emitting section belonging to the second light emitting region.

10. The detection apparatus according to claim 1,
wherein each of the first light emitting region and the second light emitting region is divided into a plurality of light emitting sections having at least one light emitting element,
the drive unit makes each of the plurality of light emitting sections emit light independently, and
an amount of power supplied to the light emitting section belonging to the first light emitting region is greater than an amount of power supplied to the light emitting section belonging to the second light emitting region.

11. The detection apparatus according to claim 1,
wherein each of the first light emitting region and the second light emitting region is divided into a plurality of light emitting sections having at least one light emitting element,
the light emitting unit has a third light emitting region that shares at least a part of light emitting sections with the first light emitting region and/or the second light emitting region,
the third light emitting region radiates light to a third radiation region that shares at least a part of a region with the first radiation region and/or the second radiation region, and
the drive unit makes each of the light emitting sections emit light independently, and in a case where radiation of light to the third radiation region is not required, makes light emitting sections configuring the third light emitting region not emit light.

12. The detection apparatus according to claim 1,
wherein the light emitting unit includes an optical member that changes a path of radiated light to make an amount of light radiated from the first light emitting region greater than an amount of light radiated from the second light emitting region.

13. The detection apparatus according to claim 12,
wherein the optical member is provided corresponding to each of the light emitting elements belonging to the first light emitting region in the light emitting unit.

14. The detection apparatus according to claim 13,
wherein the optical member provided corresponding to each of the light emitting elements belonging to the first light emitting region in the light emitting unit is a convex lens of which an optical axis is shifted with respect to the light emitting element, and directs light radiated from the first light emitting region to the first radiation region side.

15. The detection apparatus according to claim 2,
wherein the light emitting unit includes an electrode that is provided to supply a current to the light emitting unit, and
the electrode is provided with a current supply path through which a current is supplied along the first light emitting region.

16. The detection apparatus according to claim 1,
wherein the light emitting element is a vertical cavity surface emitting laser.

17. A detection system comprising:
a plurality of detection apparatuses according to claim 1,
wherein an interval between one detection apparatus and another detection apparatus is greater in a direction in which the first light emitting region of the one detection apparatus is positioned in the light emitting unit than in a direction in which the second light emitting region of the one detection apparatus is positioned in the light emitting unit.

18. The detection system according to claim 17,
wherein the plurality of detection apparatuses are arranged on a ceiling side of a passage provided between two rows of display racks arranged to face each other in a store, and
a direction in which the interval between the one detection apparatus and the other detection apparatus is large is a direction of the passage.

19. A light emitting device comprising:
a substrate;
a first light emitting region that has at least one light emitting element disposed on the substrate and radiates light to a first radiation region; and
a second light emitting region that has at least one light emitting element disposed on the substrate and radiates light to a second radiation region positioned inside with respect to the first light emitting region,
wherein the first light emitting region is smaller in area than the second light emitting region.

20. A light emitting device comprising:
a first light emitting region that has at least one light emitting element and radiates light to a first radiation region; and
a second light emitting region that has at least one light emitting element and radiates light to a second radiation region positioned inside with respect to the first light emitting region,
wherein the number of light emitting elements per unit area in the first light emitting region is greater than the number of light emitting elements per unit area in the second light emitting region.
